(19) United States
(12) Patent Application Publication
(10) Pub. No.: US 2019/0264099 A1
(43) Pub. Date: Aug. 29, 2019

(54) RESIN POWDER, WAVELENGTH CONVERSION PLATE, LIGHT-EMITTING DEVICE, AND METHOD OF FABRICATING RESIN POWDER

(71) Applicant: PANASONIC INTELLECTUAL PROPERTY MANAGEMENT CO., LTD., Osaka (JP)

(72) Inventors: Masumi ABE, Osaka (JP); Toshiaki KURACHI, Kyoto (JP)

(73) Assignee: PANASONIC INTELLECTUAL PROPERTY MANAGEMENT CO., LTD., Osaka (JP)

(21) Appl. No.: 16/254,118

(22) Filed: Jan. 22, 2019

(30) Foreign Application Priority Data
Feb. 26, 2018 (JP) 2018-031608

(51) Int. Cl. C09K 11/02; H01L 33/06; H01L 33/50; C08J 3/09; C08J 3/12

(52) U.S. Cl. CPC C09K 11/02; H01L 33/06; H01L 33/502; B82Y 20/00; C08J 3/095; C08J 3/12; H01L 33/507

(57) ABSTRACT

A resin powder includes resin particles each binding a first quantum dot phosphor.

### CROSS REFERENCE TO RELATED APPLICATION

This application claims the benefit of priority of Japanese Patent Application Number 2018-031608 filed on Feb. 26, 2018, the entire content of which is hereby incorporated by reference.

### BACKGROUND

### 1. Technical Field

The present disclosure relates to a resin powder including quantum dot phosphors, a wavelength conversion plate including the resin powder, a light-emitting device including the wavelength conversion plate, and a method of fabricating a resin powder including quantum dot phosphors.

### 2. Description of the Related Art

Conventionally known light-emitting devices include those that combine light-emitting elements such as LED (light-emitting diode) chips and phosphors (phosphor particles) that emit light when excited by light emitted from the LED chips, to emit light having a different color from the light emitted from the LED chips. As an example of such light-emitting devices, Japanese Unexamined Patent Application Publication No. 2011-134934 discloses a light-emitting device that can increase the light emission efficiency and less easily causes a luminance decrease associated with a temperature increase.

### SUMMARY

Recent years have seen cases where quantum dot phosphors are used as phosphors from the viewpoint of wavelength selectivity. The quantum dot phosphors (quantum dot phosphor particles) have a nanometer-order particle size, and it is known that quantum dot phosphors that are identical in composition emit fluorescence having different wavelengths if they are different in particle size. Thus, adjustment of the particle size of the quantum dot phosphors enables fabrication of quantum dot phosphors that emit fluorescence having a desired wavelength.

The quantum dot phosphors are difficult to be dispersed (i.e., poorly dispersible) in a silicone resin widely used as a binder for phosphors.

The present disclosure provides a resin powder and the related technologies that enhance the dispersibility of quantum dot phosphors.

A resin powder according to an aspect of the present disclosure is a resin powder including resin particles each binding a first quantum dot phosphor.

A wavelength conversion plate according to an aspect of the present disclosure is a wavelength conversion plate including a plate body and a silicone resin layer that is provided on a main surface of the plate body and binds the above resin powder.

A light-emitting device according to an aspect of the present disclosure is a light-emitting device including a base, a light-emitting element mounted on the base, and the above wavelength conversion plate that covers the light-emitting element, wherein the first quantum dot phosphor emits fluorescence when excited by at least a portion of light emitted by the light-emitting element.

A method of fabricating a resin powder according to an aspect of the present disclosure is a method including: dispersing a quantum dot phosphor in a solvent; dispersing, in a resin, the quantum dot phosphor dispersed in the solvent; solidifying the resin in which the quantum dot phosphor is dispersed; and powderizing the resin in which the quantum dot phosphor is dispersed.

With a resin powder and the related technologies according to an aspect of the present disclosure, the dispersibility of quantum dot phosphors can be enhanced.

### BRIEF DESCRIPTION OF DRAWINGS

The figures depict one or more implementations in accordance with the present teaching, by way of examples only, not by way of limitations. In the figures, like reference numerals refer to the same or similar elements.

FIG. 1 is an external perspective view of a light-emitting device and peripheral members thereof according to an embodiment;

FIG. 2 is a cross sectional view of the light-emitting device according to the embodiment;

FIG. 3 is a cross sectional view illustrating the details of a wavelength conversion plate and a light-emitting module according to the embodiment;

FIG. 4 is a flow chart illustrating processes for fabricating a resin powder and the wavelength conversion plate according to the embodiment;

FIG. 5 illustrates processes for fabricating the resin powder according to the embodiment;

FIG. 6 illustrates a resin powder according to Variation 1; and

FIG. 7 illustrates a wavelength conversion plate according to Variation 2.

### DETAILED DESCRIPTION OF EMBODIMENT

Hereinafter, an embodiment will be described with reference to the drawings. Note that the embodiment below describes a general or specific example. The numerical values, shapes, materials, structural elements, and the arrangement and connection of the structural elements, etc. presented in the embodiment below are mere examples and do not limit the present disclosure. Furthermore, among the structural elements in the embodiment below, those not recited in any of the independent claims representing the most generic concepts will be described as optional structural elements.

Note also that each figure is a schematic illustration and not necessarily a precise illustration. Throughout the figures, the same reference signs are given to essentially the same structural elements, and redundant descriptions may be omitted or simplified.

Note that in the description, the term “substantially” includes deviations within fabricating or placement margins of errors. For example, the expression “substantially evenly dispersed” is used with intention to include not only perfectly evenly dispersed, but also what would be recognized as essentially evenly dispersed.

### Embodiment

### [Overall Configuration of Light-Emitting Device]

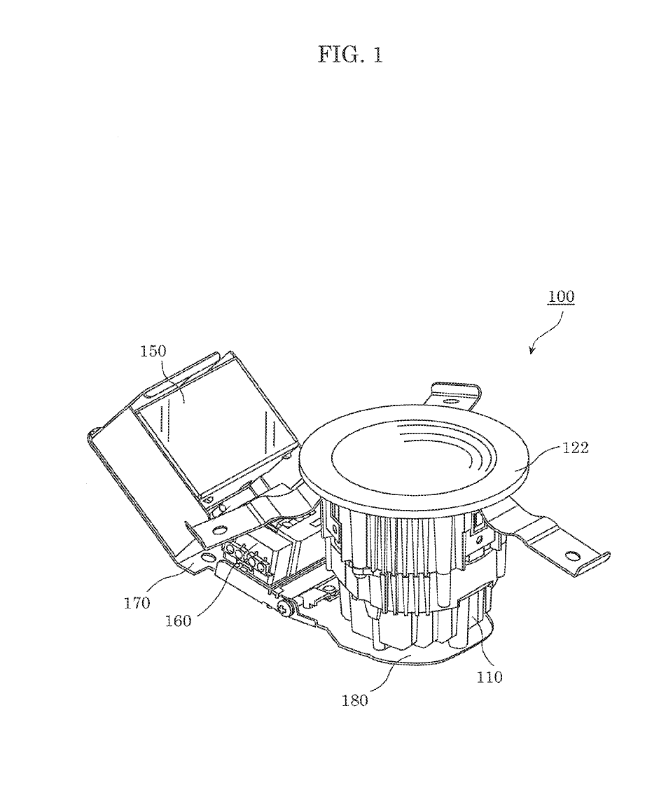

First, configurations of a resin powder, a wavelength conversion plate, and a light-emitting device according to an embodiment will be described with reference to FIG. 1 to FIG. 3.

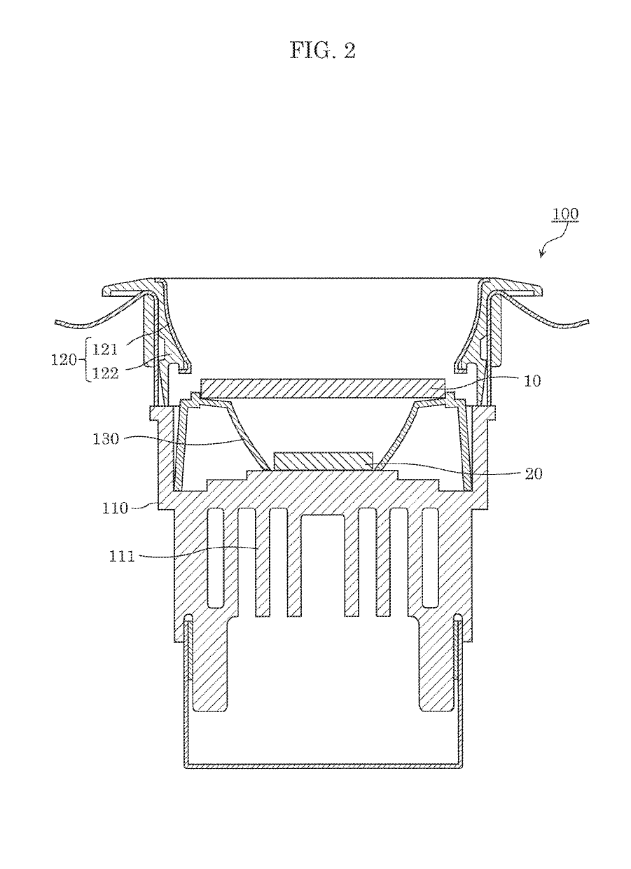

FIG. 1 is an external perspective view of light-emitting device 100 according to the embodiment. FIG. 2 is a cross sectional view of light-emitting device 100 according to the embodiment.

As illustrated in FIG. 1 and FIG. 2, light-emitting device 100 according to the embodiment is, for example, a recessed light that is installed in the ceiling of a house or the like, to emit light to a downward space (such as a corridor or a wall).

Light-emitting device 100 includes: light-emitting module 20 including base 21 and light-emitting elements 22 mounted on base 21; and wavelength conversion plate 10 covering light-emitting elements 22. Light-emitting device 100 includes: a fixture body having a substantially closed-bottom tubular shape and including pedestal 110 and frame unit 120 coupled to each other; reflector 130; lighting device 150; terminal block 160, attachment plate 170, and top plate 180.

### [Pedestal, Frame Unit, and Reflector]

Pedestal 110 is an attachment base to which light-emitting module 20 is attached, and is a heat sink for dissipating heat generated by light-emitting module 20. Pedestal 110 is formed into a substantially cylindrical shape using a metal material. In the embodiment, pedestal 110 is an aluminum die cast.

A plurality of heat-dissipating fins 111 protruding upward are provided at regular intervals along one direction on an upper portion (ceiling-side portion) of pedestal 110. This enables heat generated by light-emitting module 20 to be efficiently dissipated.

Frame unit 120 includes substantially cylindrical cone portion 121 having a reflective surface on the inner surface and frame body 122 to which cone portion 121 is attached. Cone portion 121 is formed using a metal material and is, for example, manufactured by metal spinning or pressing an aluminum alloy or the like. Frame body 122 is formed from a hard resin material or a metal material. Frame unit 120 is fixed by attaching frame body 122 to pedestal 110.

Reflector 130 is an annular frame shaped (funnel shaped) reflection member whose inner surface is reflective. For example, reflector 130 is formed using a metal material such as aluminum. Note that reflector 130 may be formed from a hard white resin material instead of a metal material.

### [Lighting Device, Terminal Block, Attachment Plate, and Top Plate]

As illustrated in FIG. 1, light-emitting device 100 includes lighting device 150 that supplies light-emitting module 20 with power for causing light-emitting module 20 to emit light, and terminal block 160 that relays AC power from an external commercial power supply (not illustrated) to lighting device 150. Specifically, lighting device 150 converts the AC power relayed by terminal block 160 into DC power, and outputs the DC power to light-emitting module 20.

Lighting device 150 and terminal block 160 are fixed to attachment plate 170 provided separately from the fixture body. Attachment plate 170 is formed by bending a rectangular plate member made of a metal material. Lighting device 150 is fixed to the lower surface of one longitudinal end of attachment plate 170, and terminal block 160 is fixed to the lower surface of the other longitudinal end of attachment plate 170. Attachment plate 170 is coupled with top plate 180 fixed to the upper portion of pedestal 110 of the fixture body.

### [Light-Emitting Module]

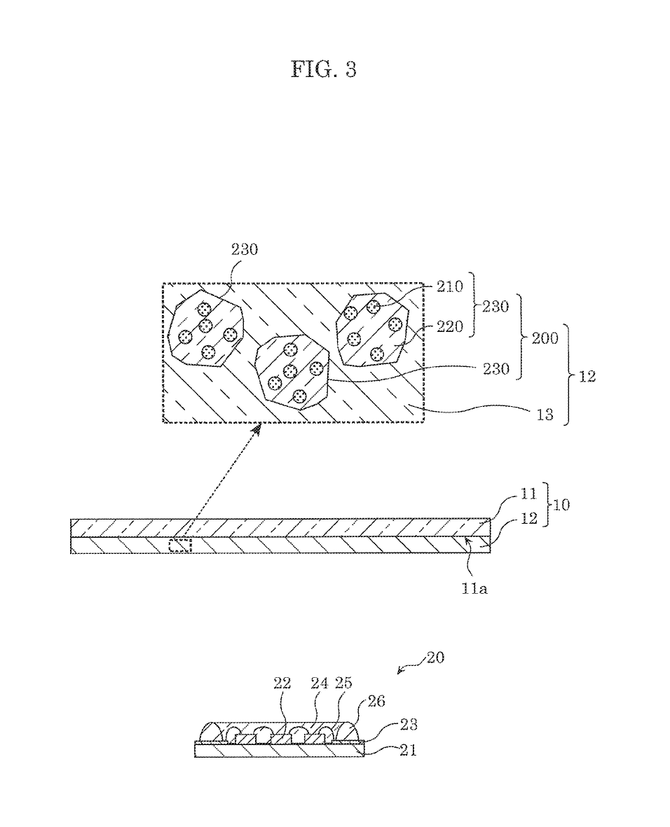

FIG. 3 is a cross sectional view illustrating the details of wavelength conversion plate 10 and light-emitting module 20 according to the embodiment.

Light-emitting module 20 has a plurality of light-emitting elements 22 directly mounted on base 21. In the present embodiment, light-emitting module 20 is a COB (chip-on-board) LED (light-emitting diode) module that uses LED chips as light-emitting elements 22, and emits blue light.

Base 21 is a substrate having a wiring region in which wiring 23 is provided. Wiring 23 is for supplying light-emitting elements 22 with power and is formed from a metal material. Base 21 has an electrode provided thereon as a part of the wiring for electrically connecting light-emitting module 20 and an external device. Base 21 is a metal-based substrate or a ceramic substrate, for example. Base 21 may be a resin substrate that uses a resin as a base material.

The ceramic substrate is, for example, an alumina substrate made of aluminum oxide (alumina) or an aluminum nitride substrate made of aluminum nitride. The metal-based substrate is, for example, an aluminum alloy substrate, an iron alloy substrate, or a copper alloy substrate which include an insulating film on a surface thereof. The resin substrate is, for example, a glass-epoxy substrate made of glass fiber and an epoxy resin.

Note that a substrate having a high reflectivity (for example, a reflectivity of 90% or higher), for example, may be used as base 21. Using a substrate having a high reflectivity as base 21 allows light emitted by light-emitting elements 22 to be reflected off the surface of base 21. This results in an increase in the light extraction efficiency of light-emitting module 20. Such a substrate is, for example, a white ceramic substrate that includes alumina as a base material.

Base 21 may be a light-transmissive substrate having a high light transmittance. Such a substrate is, for example, a light-transmissive ceramic substrate made of polycrystalline alumina or aluminum nitride, a transparent glass substrate made of glass, a quartz substrate made of quartz, a sapphire substrate made of sapphire, or a transparent resin substrate made of a transparent resin material. Note that base 21 is, for example, rectangular in a plan view, but may be circular or have any other shape.

Light-emitting elements 22 are disposed (mounted) on base 21. In the present embodiment, light-emitting elements 22 are, for example, blue LED chips formed from a gallium nitride material such as InGaN (indium gallium nitride) and having a center wavelength (a peak wavelength in the emission spectrum) in a range from 420 nm to 460 nm, both inclusive. In other words, light-emitting elements 22 emit blue light. Light-emitting elements 22 are electrically connected with wiring 23 via bonding wire 25 made of a metal material such as gold.

A plurality of light-emitting elements 22 are disposed on base 21, but disposing at least one light-emitting element 22 is sufficient. The plurality of light-emitting elements 22 may be disposed on base 21 in any manner. Moreover, the plurality of light-emitting elements 22 may be electrically connected in any manner.

Sealant 24 seals light-emitting elements 22, bonding wire 25, and at least a portion of wiring 23. Sealant 24 is formed of, for example, a light-transmissive resin material that transmits light emitted by light-emitting elements 22. The light-transmissive resin material is, but not limited to, a methyl-based silicone resin, an epoxy resin, or a urea resin, for example.

Dam member 26 is provided on base 21, surrounding light-emitting elements 22 so as to block sealant 24. Dam member 26 is formed from, for example, an insulating and thermosetting resin or thermoplastic resin. More specifically, dam member 26 is formed from, for example, a silicone resin, a phenol resin, an epoxy resin, a bismaleimide-triazine resin, or a PPA (polyphthalamide) resin. Note that dam member 26 may be formed from a material other than resin. Dam member 26 may be ceramic, for example. For example, a light dispersing agent such as titanium oxide that reflects light emitted from light-emitting elements 22 is added to dam member 26. Moreover, dam member 26 is white, for example, so as to reflect light emitted from light-emitting elements 22.

### [Wavelength Conversion Plate]

Wavelength conversion plate 10 is a plate-shaped member including quantum dot phosphors (first quantum dot phosphors) 210 that emit fluorescence when excited by at least a portion of light emitted from light-emitting module 20 (specifically, light-emitting elements 22). Wavelength conversion plate 10 is disposed in a manner that main surface 11a faces light-emitting module 20, for example. More specifically, wavelength conversion plate 10 is disposed in a manner that main surface 11a of plate body 11 is orthogonal to the optical axis of light-emitting module 20. Wavelength conversion plate 10 is disposed separately from light-emitting module 20, on the light emission side of light-emitting module 20. In other words, wavelength conversion plate 10 is irradiated with blue light emitted by light-emitting module 20.

Wavelength conversion plate 10 specifically includes plate body 11 and silicone resin layer 12 that is provided on main surface 11a of plate body 11 and binds resin powder 200.

Plate body 11 is formed from, for example, a light-transmissive resin material such as an acrylic resin or a polycarbonate resin, but may be formed from a light-transmissive ceramic material or the like. For example, plate body 11 transmits light emitted by light-emitting elements 22. Plate body 11 also transmits fluorescence emitted by resin powder 200. That is to say, plate body 11 transmits fluorescence emitted by first quantum dot phosphors 210 included in resin powder 200. In the present embodiment, plate body 11 transmits light emitted by light-emitting elements 22 and fluorescence emitted by first quantum dot phosphors 210. The thickness of wavelength conversion plate 10 is 1 mm or less, for example, but may be 100 μm or less.

Silicone resin layer 12 is a wavelength conversion layer in which silicone resin 13 binds resin powder 200 that is an aggregation of phosphor resin particles 230 including resin particles 220 containing first quantum dot phosphors 210 that emit fluorescence when excited by at least a portion of light emitted by light-emitting elements 22. Silicone resin layer 12 includes, for example, bonding silicone resin 13 including resin powder 200, bonded to plate body 11 by thermocompression. Silicone resin layer 12 includes first quantum dot phosphors 210 and silicone resin 13 that binds resin powder 200 that is an aggregation of phosphor resin particles 230 including resin particles 220 containing first quantum dot phosphors 210.

Resin powder 200 includes resin particles each binding first quantum dot phosphors 210. Specifically, resin powder 200 includes resin particles 220 formed from a solidified resin being powderized, and each resin particle 220 includes first quantum dot phosphors 210 bound by resin particle 220. Put another way, resin powder 200 includes resin particles 220 formed from a solidified resin being powderized, and also includes, in each resin particle 220, first quantum dot phosphors 210 bound by resin particle 220. Resin powder 200 is substantially evenly dispersed in silicone resin layer 12.

When excited by primary light emitted by light-emitting elements 22 included in light-emitting module 20 (that is, blue light), first quantum dot phosphors 210 emit, as fluorescence, secondary light longer in wavelength than the primary light. First quantum dot phosphors 210 are quantum dot phosphors containing a semiconductor material, for example. Specifically, first quantum dot phosphors 210 are expressed by a chemical formula of CdSₓSe₁₋ₓ/ZnS, but may be cadmium free. Changes in at least one of composition and shape of first quantum dot phosphors 210 allows first quantum dot phosphors 210 to emit light of various emission peak wavelengths. The particle size of first quantum dot phosphors 210, which is nanometer-order, is about 10 nm to 20 nm, for example.

When light-emitting module 20 emits primary light (that is, blue light), the wavelength of a portion of the primary light is converted into that of secondary light by first quantum dot phosphors 210 included in wavelength conversion plate 10. As a result, light-emitting device 100 emits light including the primary light not absorbed by first quantum dot phosphors 210 and the secondary light obtained through the wavelength conversion by first quantum dot phosphors 210.

Resin particles 220 are a thermoplastic or thermosetting resin that binds first quantum dot phosphors 210. In the present embodiment, each resin particle 220 binds a plurality of first quantum dot phosphors 210 (first quantum dot phosphor 210 particles). Each resin particle 220 may bind one first quantum dot phosphor 210. In addition, first quantum dot phosphors 210 may be enclosed by resin particles 220 or may be partially exposed from the surface of resin particles 220. Silicone resin layer 12 dispersedly contains resin powder 200 including phosphor resin particles 230 having first quantum dot phosphors 210 and resin particles 220 binding first quantum dot phosphors 210.

Note that wavelength conversion plate 10 may have a laminated structure in which silicone resin layer 12 is sandwiched between two plate bodies 11.

Silicone resin 13 may be a thermoplastic resin or a thermosetting resin.

### [Fabricating Method]

The inventors have achieved substantially even dispersion of first quantum dot phosphors 210 in silicone resin 13, by using resin powder 200 that is an aggregation of phosphor resin particles 230 in which first quantum dot phosphors 210 are bound by resin particles 220.

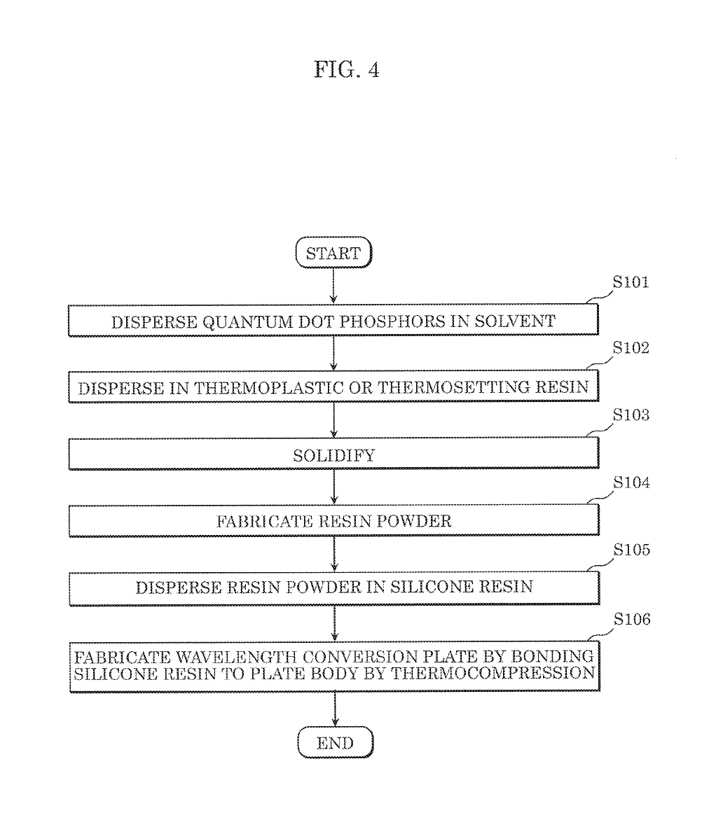

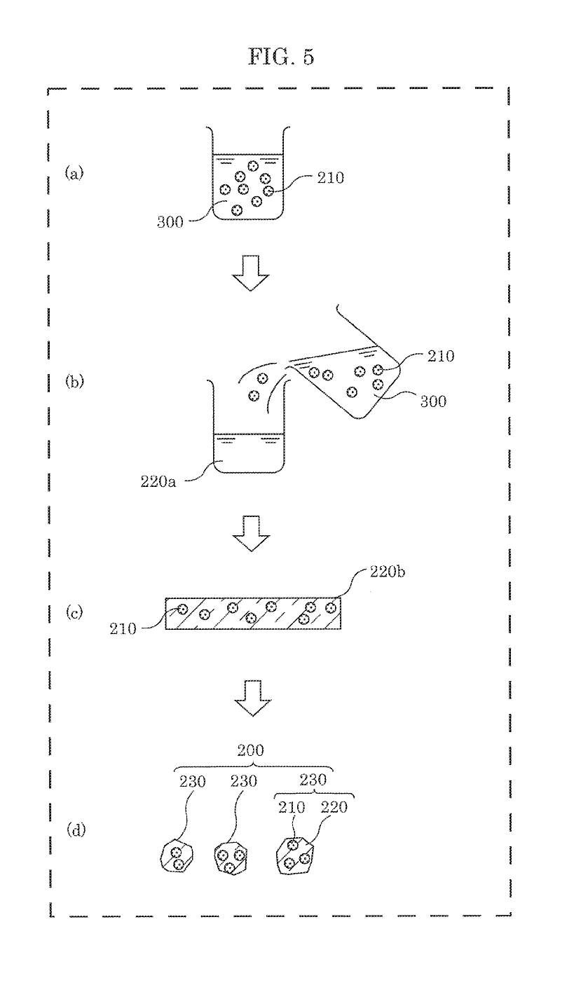

The following describes, with reference to FIG. 4 and FIG. 5, a method of fabricating resin powder 200 and wavelength conversion plate 10 including silicone resin 13 in which resin powder 200 is dispersed.

FIG. 4 is a flow chart illustrating processes for fabricating resin powder 200 and wavelength conversion plate 10 according to the embodiment. FIG. 5 illustrates processes for fabricating resin powder 200 according to the embodiment. Note that first quantum dot phosphors 210 in (a) and (b) in FIG. 5 are shown with dot hatching, although they are not cross sections. FIG. 5 illustrates, in (c) and (d), cross sectional views including the cross sections of first quantum dot phosphors 210.

As illustrated in FIG. 4 and (a) in FIG. 5, first, quantum dot phosphors (first quantum dot phosphors) 210 are mixed with solvent 300 that is a liquid organic solvent such as acrylic, and stirred, so that first quantum dot phosphors 210 are dispersed in solvent 300 (Step S101).

Next, as illustrated in FIG. 4 and (b) in FIG. 5, solvent 300 in which first quantum dot phosphors 210 are dispersed is mixed with a thermoplastic or thermosetting liquid (or semi-solid) resin (liquid resin 220a) and stirred, so that first quantum dot phosphors 210 are dispersed in liquid resin 220a (Step S102). Liquid resin 220a is a precursor of later-described solid resin 220b and resin particles 220. An acrylic resin is an example of the thermoplastic resin and an epoxy resin is an example of the thermosetting resin; however the material of the resins is not limited to these examples.

Next, as illustrated in FIG. 4 and (c) in FIG. 5, liquid resin 220a in which first quantum dot phosphors 210 are dispersed is solidified by heating or cooling, so that solid resin 220b, that is liquid resin 220a being solidified, binds first quantum dot phosphor 210 (that is, holds the positions of first quantum dot phosphors 210) (Step S103). The shape of solid resin 220b is not particularly limited. For example, solid resin 220b has such a shape as a sheet-like shape that allows easy pulverization in Step S104 described below.

Next, as illustrated in FIG. 4 and (d) in FIG. 5, solid resin 220b containing first quantum dot phosphors 210 is pulverized for powderization, to fabricate resin powder 200 that is an aggregation of phosphor resin particles 230 that are resin particles 220 containing first quantum dot phosphors 210 (Step S104).

In such a manner as described above, resin powder 200 is fabricated by dispersing first quantum dot phosphors 210 in solvent 300 (Step S101), dispersing, in a resin (liquid resin 220a), first quantum dot phosphors 210 dispersed in solvent 300 in Step S101 (Step S102), solidifying the resin (liquid resin 220a) in which first quantum dot phosphors 210 are dispersed in Step S102 (Step S103), and powderizing, into resin powder 200, a resin (solid resin 220b) in which first quantum dot phosphors 210 are dispersed and which has been solidified in Step S103 (Step S104).

Note that the shape of phosphor resin particles 230 (specifically, resin particles 220) included in resin powder 200 is not particularly limited because phosphor resin particles 230 are powderized through pulverization of bulk solidified resin. The particle size of phosphor resin particles 230 (specifically, resin particles 220) is, but not particularly limited to, about 10 μm to 20 μm, for example.

Next, as illustrated in FIG. 4, resin powder 200 is mixed with silicone resin 13 and stirred, so that resin powder 200 is dispersed in silicone resin 13 (Step S105).

Next, as illustrated in FIG. 4, silicone resin 13 in which resin powder 200 is dispersed is bonded to plate body 11 by thermocompression, so that silicone resin layer 12 is formed on plate body 11 and wavelength conversion plate 10 is thereby fabricated (Step S106). In Step S106, wavelength conversion plate 10 is fabricated by, for example, softening silicone resin 13 containing first quantum dot phosphors 210 by heating to about 100° C., and pressing softened silicone resin 13 against plate body 11.

### [Variation 1]

In the above embodiment, one type of quantum dot phosphors is contained in resin particles 220, but a plurality of types of quantum dot phosphors may be contained.

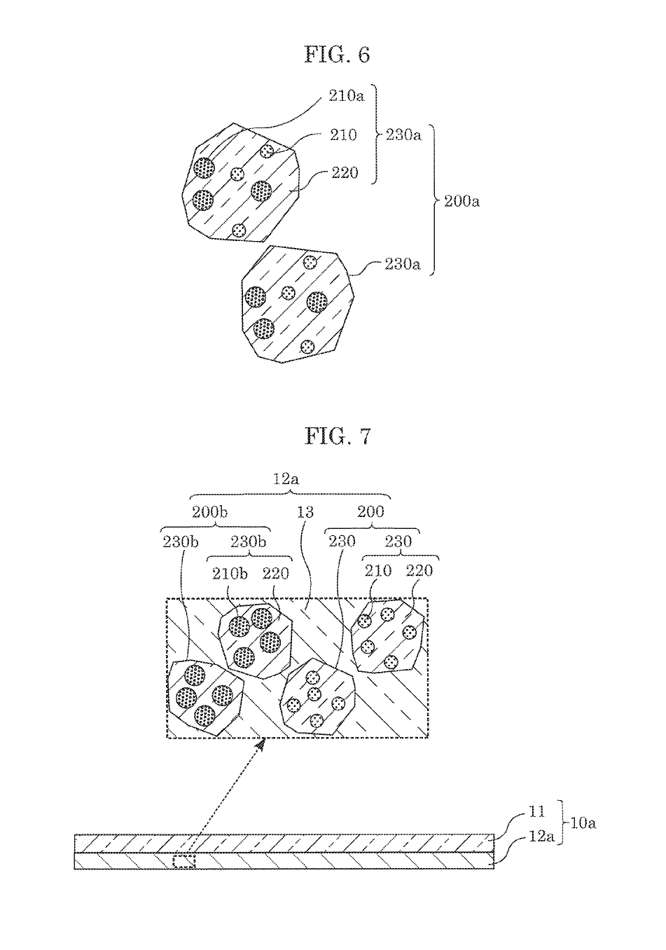

FIG. 6 illustrates resin powder 200a according to Variation 1 of the embodiment.

Resin powder 200a includes phosphor resin particles 230a. Each phosphor resin particle 230a includes first quantum dot phosphors 210, second quantum dot phosphors 210a, and resin particle 220 that binds first quantum dot phosphors 210 and second quantum dot phosphors 210a.

When excited by primary light emitted by light-emitting elements 22 included in light-emitting module 20, second quantum dot phosphors 210a emit, as fluorescence, secondary light longer in wavelength than the primary light. Second quantum dot phosphors 210a are quantum dot phosphors containing a semiconductor material, for example. Specifically, second quantum dot phosphors 210a are quantum dot phosphors expressed by a chemical formula of CdSₓSe₁₋ₓ/ZnS, containing cadmium, but may be cadmium free. The particle size of second quantum dot phosphors 210a, which is nanometer-order, is about 10 nm to 20 nm, for example.

The fluorescence spectrum of the fluorescence emitted by second quantum dot phosphors 210a is different from the fluorescence spectrum of the fluorescence emitted by first quantum dot phosphors 210 in at least one of peak wavelength and half width. That is to say, resin powder 200a includes resin particles 220 each binding, in addition to first quantum dot phosphors 210, second quantum dot phosphors 210a that emit fluorescence having a fluorescence spectrum different from the fluorescence spectrum of the fluorescence emitted by first quantum dot phosphors 210 in at least one of peak wavelength and half width. In other words, unlike resin powder 200, resin powder 200a includes, in addition to first quantum dot phosphors 210, second quantum dot phosphors 210a that emit fluorescence having a fluorescence spectrum different from the fluorescence spectrum of the fluorescence emitted by first quantum dot phosphors 210 in at least one of peak wavelength and half width. Specifically, second quantum dot phosphors 210a are bound by resin particles 220 binding first quantum dot phosphors 210.

The fluorescence spectrum of the fluorescence emitted by first quantum dot phosphors 210 and the fluorescence spectrum of the fluorescence emitted by second quantum dot phosphors 210a may be made different from each other in at least one of peak wavelength and half width by making the compositions of first quantum dot phosphors 210 and second quantum dot phosphors 210a different from each other. However, these fluorescence spectra may be made different from each other in at least one of peak wavelength and half width by, for example, making the compositions of first quantum dot phosphors 210 and second quantum dot phosphors 210a identical and making the respective particle sizes different.

### [Variation 2]

In the above embodiment, resin powder 200 that includes an aggregation of resin particles 220 including first quantum dot phosphors 210 is dispersed in silicone resin layer 12. In addition to resin powder 200, a resin powder that includes an aggregation of resin particles including quantum dot phosphors different from first quantum dot phosphors 210 may also be dispersed in silicone resin layer 12.

FIG. 7 illustrates wavelength conversion plate 10a according to Variation 2 of the embodiment.

As with wavelength conversion plate 10, wavelength conversion plate 10a is a plate-shaped member including quantum dot phosphors that emit fluorescence when excited by at least a portion of light emitted from light-emitting module 20 (specifically, light-emitting elements 22).

Specifically, wavelength conversion plate 10a includes plate body 11 and silicone resin layer 12a.

Silicone resin layer 12a is a wavelength conversion layer in which silicone resin 13 binds resin powder 200 that is an aggregation of phosphor resin particles 230 including resin particles 220 containing first quantum dot phosphors 210 that emit fluorescence when excited by at least a portion of light emitted by light-emitting elements 22. Silicone resin layer 12a includes second resin powder 200b that is bound by silicone resin 13 and is an aggregation of phosphor resin particles 230b including resin particles 220 containing third quantum dot phosphors 210b. That is to say, silicone resin layer 12a includes first quantum dot phosphors 210, third quantum dot phosphors 210b, and silicone resin 13.

When excited by primary light emitted by light-emitting elements 22 included in light-emitting module 20, third quantum dot phosphors 210b emit, as fluorescence, secondary light longer in wavelength than the primary light. Third quantum dot phosphors 210b are quantum dot phosphors containing a semiconductor material, for example. Specifically, third quantum dot phosphors 210b are quantum dot phosphors expressed by a chemical formula of CdSₓSe₁₋ₓ/ZnS, containing cadmium, but may be cadmium free. The particle size of third quantum dot phosphors 210b, which is nanometer-order, is about 10 nm to 20 nm, for example.

The fluorescence spectrum of the fluorescence emitted by third quantum dot phosphors 210b is different from the fluorescence spectrum of the fluorescence emitted by first quantum dot phosphors 210 in at least one of peak wavelength and half width. In other words, unlike resin powder 200, second resin powder 200b includes third quantum dot phosphors 210b that emit fluorescence having a fluorescence spectrum different from the fluorescence spectrum of the fluorescence emitted by first quantum dot phosphors 210 in at least one of peak wavelength and half width. Specifically, third quantum dot phosphors 210b are bound by resin particles 220 different from resin particles 220 binding first quantum dot phosphors 210. More specifically, silicone resin layer 12a further includes, in addition to resin powder 200, second resin powder 200b including third quantum dot phosphors 210b that emit fluorescence having a fluorescence spectrum different from the fluorescence spectrum of the fluorescence emitted by first quantum dot phosphors 210 in at least one of peak wavelength and half width.

Note that the configuration of second resin powder 200b is the same as that of resin powder 200 except for the quantum dot phosphors, and the fabricating method of second resin powder 200b is also the same as that of resin powder 200.

The fluorescence spectrum of the fluorescence emitted by first quantum dot phosphors 210 and the fluorescence spectrum of the fluorescence emitted by third quantum dot phosphors 210b may be made different from each other in at least one of peak wavelength and half width by making the compositions of first quantum dot phosphors 210 and third quantum dot phosphors 210b different from each other. However, these fluorescence spectra may be made different from each other in at least one of peak wavelength and half width by, for example, making the compositions of first quantum dot phosphors 210 and third quantum dot phosphors 210b identical and making the respective particle sizes different.

When light-emitting module 20 emits primary light, the wavelength of a portion of the primary light is converted into that of secondary light by first quantum dot phosphors 210 and third quantum dot phosphors 210b included in wavelength conversion plate 10a.

Note that wavelength conversion plate 10a may have a laminated structure in which silicone resin layer 12a is sandwiched between two plate bodies 11.

### [Advantageous Effects, Etc.]

As described above, resin powder 200 according to the embodiment includes resin particles 220 each binding first quantum dot phosphor 210.

Each of resin particles 220 included in resin powder 200 is larger than first quantum dot phosphor 210 in particle size. Moreover, first quantum dot phosphor 210 is dispersed in each of resin particles 220. Accordingly, resin powder 200 facilitates even dispersion of first quantum dot phosphor 210 in silicone resin 13, for example, as compared to first quantum dot phosphor 210. That is to say, dispersion of resin powder 200 in, for example, silicone resin 13 facilitates even dispersion of first quantum dot phosphor 210 in, for example, silicone resin 13 without agglomeration of the particles of first quantum dot phosphor 210, as compared to the case where first quantum dot phosphor 210 is dispersed in, for example, silicone resin 13 without being bound (held) by resin particles 220. In such a manner as described, resin powder 200 can enhance the dispersibility of first quantum dot phosphor 210.

For example, each of resin particles 220 further binds second quantum dot phosphor 210a that emits fluorescence having a fluorescence spectrum different from a fluorescence spectrum of fluorescence emitted by first quantum dot phosphor 210 in at least one of peak wavelength and half width. In other words, resin powder 200a further includes second quantum dot phosphor 210a that emits fluorescence having a fluorescence spectrum different from the fluorescence spectrum of the fluorescence emitted by first quantum dot phosphor 210 in at least one of peak wavelength and half width. For example, second quantum dot phosphor 210a is bound by resin particles 220 binding first quantum dot phosphor 210.

Accordingly, when a plurality of types of quantum dot phosphors having different emission spectra are dispersed in, for example, silicone resin 13, the respective types of quantum dot phosphors are more easily dispersed.

For example, first quantum dot phosphor 210 and second quantum dot phosphor 210a are identical in composition and different in particle size.

Use of quantum dot phosphors identical in composition as stated above eliminates the necessity to use a plurality of types of quantum dot phosphors different in composition, thereby allowing easier and simpler fabrication of resin powder 200a.

For example, resin particles 220 are thermoplastic particles or thermosetting particles.

This facilitates a state change from liquid resin 220a, that is a precursor of resin particles 220, to a solid resin. Thus, such a configuration as described above enables easier and simpler fabrication of resin powder 200.

Wavelength conversion plate 10 according to the embodiment includes plate body 11 and silicone resin layer 12 that is provided on main surface 11a of plate body 11 and binds resin powder 200.

Such a configuration facilitates even dispersion of resin powder 200 in silicone resin layer 12 of wavelength conversion plate 10. That is to say, use of resin powder 200 including first quantum dot phosphor 210 having enhanced dispersibility facilitates even dispersion of first quantum dot phosphor 210 in silicone resin layer 12 of wavelength conversion plate 10.

Conventional wavelength conversion plates (in other words, quantum dot phosphor sheets) are fabricated by dispersing quantum dot phosphors in a resin material such as an acrylic resin and forming the resultant into a sheet. The quantum dot phosphor sheet formed in this manner, however, is fragile and has a problem in handling. In addition, the quantum dot phosphor sheet fabricated using an acrylic resin as a raw material has a problem of being vulnerable to heat.

Silicone resin 13 is used in wavelength conversion plate 10 according to the embodiment as a binder for first quantum dot phosphors 210. Further, resin powder 200 including first quantum dot phosphors 210 and more dispersible than first quantum dot phosphors 210 is used in wavelength conversion plate 10. Thus, wavelength conversion plate 10 has high thermal durability and is easy to handle as compared to the conventional quantum dot phosphor sheets.

For example, plate body 11 transmits fluorescence emitted by resin powder 200. That is to say, plate body 11 transmits the fluorescence emitted by first quantunm dot phosphor 210 included in resin powder 200. Moreover, plate body 11 transmits, for example, the fluorescence emitted by first quantum dot phosphor 210 and second quantum dot phosphor 210a included in resin powder 200a. Moreover, plate body 11 transmits, for example, the fluorescence emitted by first quantum dot phosphor 210 and third quantum dot phosphor 210b included in resin powder 200b.

Accordingly, wavelength conversion plates 10 and 10a can be transmissive wavelength conversion plates.

For example, silicone resin layer 12a further includes second resin powder 200b including third quantum dot phosphor 210b that emits fluorescence having a fluorescence spectrum different from a fluorescence spectrum of fluorescence emitted by first quantum dot phosphor 210 in at least one of peak wavelength and half width. Note that second resin powder 200b has the same configuration as resin powder 200 except for quantum dot phosphors.

Such a configuration can provide silicone resin layer 12a that emits different types of fluorescence, thus increasing the wavelength selectivity of wavelength conversion plate 10a.

For example, first quantum dot phosphor 210 and third quantum dot phosphor 210b are identical in composition and different in particle size.

Use of quantum dot phosphors identical in composition as stated above eliminates the necessity to use a plurality of types of quantum dot phosphors different in composition, thereby allowing easier and simpler fabrication of wavelength conversion plate 10a.

For example, resin powder 200 is substantially evenly dispersed in silicone resin layer 12. Alternatively, for example, resin powder 200a is substantially evenly dispersed in silicone resin layer 12a. Specifically, for example, resin powder 200 or resin powder 200a is substantially evenly dispersed in silicone resin 13.

This can reduce unevenness in color of light emitted from wavelength conversion plate 10 (specifically, fluorescence emitted from quantum dot phosphors).

For example, silicone resin layer 12 comprises silicone resin 13 including resin powder 200, bonded to plate body 11 by thermocompression.

Accordingly, silicone resin layer 12 does not come off easily from plate body 11.

Light-emitting device 100 according to the embodiment includes base 21, light-emitting element 22 mounted on base 21, and wavelength conversion plate 10 that covers light-emitting element 22. First quantum dot phosphor 210 emits fluorescence when excited by at least a portion of light emitted by light-emitting element 22.

With such a configuration, since the unevenness in color of light emitted from wavelength conversion plate 10 is reduced, unevenness in color of light emitted from light-emitting device 100 can also be reduced. Moreover, since wavelength conversion plate 10 is easy to handle, light-emitting device 100 can be easily and simply assembled.

For example, plate body 11 transmits the light emitted by light-emitting element 22.

Accordingly, wavelength conversion plate 10 can be a transmissive wavelength conversion plate. Moreover, with such a configuration, even when, for example, plate body 11 does not transmit fluorescence emitted by first quantum dot phosphors 210, disposing plate body 11 between silicone resin layer 12 and light-emitting elements 22 allows wavelength conversion plate 10 to be a transmissive wavelength conversion plate.

A method of fabricating resin powder 200 according to the embodiment is a method including: (a) dispersing first quantum dot phosphor 210 in solvent 300; (b) dispersing, in a resin (liquid resin 220a), first quantum dot phosphor 210 dispersed in solvent 300 in (a); (c) solidifying the resin (liquid resin 220a) in which first quantum dot phosphor 210 is dispersed in (b); and (d) powderizing, into resin powder 200, the resin (solid resin 220b) in which first quantum dot phosphor 210 is dispersed and which has been solidified in (c).

This enables fabrication of resin powder 200 that can enhance the dispersibility of first quantum dot phosphor 210.

### Other Embodiments

Although resin powder 200, 200a, wavelength conversion plate 10, 10a, light-emitting device 100, and a method of fabricating resin powder 200, 200a according to an embodiment and variations have been described above, the present disclosure is not limited to the above embodiment and variations.

For example, light-emitting device 100 in the above embodiment is a recessed light, but the light-emitting device according to the present disclosure may be a spotlight, a ceiling light, a base light, or the like, rather than a recessed light.

In the above embodiment, light-emitting elements 22 used in light-emitting device 100 are LED chips. However, semiconductor light-emitting elements such as semiconductor lasers or solid-state light-emitting elements such as organic EL (electroluminescent) elements or inorganic EL elements may be used for light-emitting elements 22.

Moreover, light-emitting module 20 in the above embodiment is a COB light-emitting module, but may be an SMD (surface mount device) light-emitting module. The SMD light-emitting module has a configuration in which SMD elements are mounted on a substrate. The SMD elements have a configuration in which light-emitting elements disposed in a container are scaled by a sealant contained in the container.

Although light-emitting device 100 according to an aspect of the present disclosure is a remote phosphor light-emitting device in which resin powder 200, 200a is dispersed in silicone resin 13 included in wavelength conversion plate 10, 10a, resin powder 200, 200a may be dispersed in, for example, sealant 24 that seals light-emitting elements 22.

A phosphor different from quantum dot phosphors (that is, a phosphor having a particle size of about several micrometers to several tens of micrometers) may be further added to sealant 24 for sealing light-emitting elements 22. Silicone resin layer 12, 12a included in wavelength conversion plate 10, 10a may also include, in addition to quantum dot phosphors, a phosphor different from quantum dot phosphors. That is to say, for wavelength conversion plate 10, 10a and light-emitting device 100 according to the present disclosure, a phosphor different from quantum dot phosphors may also be used in combination with quantum dot phosphors. A green phosphor is, for example, a Lu₃Al₅O₁₂:Ce³⁺ phosphor, a yellow phosphor is, for example, an yttrium aluminum garnet (YAG) phosphor, a red phosphor is, for example, a CaAlSiN₃:Eu²⁺ phosphor or a (Sr, Ca) AlSiNs:Eu²⁺ phosphor.

Wavelength conversion plates 10, 10a in the above embodiment are transmissive wavelength conversion plates that transmit light emitted by light-emitting elements 22, but may be reflective wavelength conversion plates. In this case, plate body 11 reflects, for example, the fluorescence emitted by first quantum dot phosphors 210 and the light emitted by light-emitting elements 22. The material of plate body 11 is, but not particularly limited to, for example, metal such as aluminum or an aluminum alloy.

In the above embodiment, silicone resin layer 12, 12a is disposed between plate body 11 and light-emitting elements 22, but plate body 11 may be disposed between silicone resin layer 12, 12a and light-emitting elements 22. In this case, plate body 11 may be formed of a material that transmits light emitted by light-emitting elements 22. Moreover, in this case, plate body 11 may be formed of a material that reflects fluorescence emitted by first quantum dot phosphors 210. In addition, in this case, a multilayer film or the like that transmits light emitted by light-emitting elements 22 and reflects fluorescence emitted by first quantum dot phosphors 210 may be formed on plate body 11.

When silicone resin layer 12 includes a plurality of types of quantum dot phosphors that emit mutually different types of fluorescence, plate body 11 transmits those types of fluorescence, for example. When wavelength conversion plate 10, 10a is of the reflective type and silicone resin layer 12, 12a includes a plurality of types of quantum dot phosphors that emit mutually different types of fluorescence, plate body 11 reflects those types of fluorescence, for example.

The present disclosure also encompasses: embodiments achieved by applying various modifications conceivable to those skilled in the art to each embodiment; and embodiments achieved by arbitrarily combining the structural elements and the functions of each embodiment without departing from the essence of the present disclosure.

While the foregoing has described one or more embodiments and/or other examples, it is understood that various modifications may be made therein and that the subject matter disclosed herein may be implemented in various forms and examples, and that they may be applied in numerous applications, only some of which have been described herein. It is intended by the following claims to claim any and all modifications and variations that fall within the true scope of the present teachings.

What is claimed is:

1. A resin powder, comprising:
resin particles each binding a first quantum dot phosphor.

2. The resin powder according to claim 1, wherein
each of the resin particles further binds a second quantum dot phosphor that emits fluorescence having a fluorescence spectrum different from a fluorescence spectrum of fluorescence emitted by the first quantum dot phosphor in at least one of peak wavelength and half width.

3. The resin powder according to claim 2, wherein
the first quantum dot phosphor and the second quantum dot phosphor are identical in composition and different in particle size.

4. The resin powder according to claim 1, wherein
the resin particles are thermoplastic particles or thermosetting particles.

5. A wavelength conversion plate, comprising:
a plate body; and
a silicone resin layer that is provided on a main surface of the plate body and binds the resin powder according to claim 1.

6. The wavelength conversion plate according to claim 5, wherein
the plate body transmits fluorescence emitted by the resin powder.

7. The wavelength conversion plate according to claim 5, wherein
the silicone resin layer further includes a second resin powder including a third quantum dot phosphor that emits fluorescence having a fluorescence spectrum different from a fluorescence spectrum of fluorescence emitted by the first quantum dot phosphor in at least one of peak wavelength and half width.

8. The wavelength conversion plate according to claim 7, wherein
the first quantum dot phosphor and the third quantum dot phosphor are identical in composition and different in particle size.

9. The wavelength conversion plate according to claim 5, wherein
the resin powder is substantially evenly dispersed in the silicone resin layer.

10. The wavelength conversion plate according to claim 5, wherein
the silicone resin layer comprises a silicone resin including the resin powder, bonded to the plate body by thermocompression.

11. A light-emitting device, comprising:
a base;
a light-emitting element mounted on the base; and
the wavelength conversion plate according to claim 5 that covers the light-emitting element, wherein
the first quantum dot phosphor emits fluorescence when excited by at least a portion of light emitted by the light-emitting element.

12. The light-emitting device according to claim 11, wherein
the plate body transmits the light emitted by the light-emitting element.

13. A method of fabricating a resin powder, the method comprising:
dispersing a quantum dot phosphor in a solvent;
dispersing, in a resin, the quantum dot phosphor dispersed in the solvent;
solidifying the resin in which the quantum dot phosphor is dispersed; and
powderizing the resin in which the quantum dot phosphor is dispersed.
